(19) United States
(12) Patent Application Publication
(10) Pub. No.: US 2015/0108992 A1
(43) Pub. Date: Apr. 23, 2015

(54) SYSTEM FOR MONITORING STATE OF BATTERY PACK

(71) Applicant: DENSO CORPORATION, Kariya-city (JP)

(72) Inventors: Masakazu KOUDA, Kariya-shi (JP); Shunichi MIZOBE, Kariya-shi (JP); Hayato MIZOGUCHI, Kariya-shi (JP)

(21) Appl. No.: 14/515,932

(22) Filed: Oct. 16, 2014

(30) Foreign Application Priority Data
Oct. 17, 2013 (JP) 2013-216131

(51) Int. Cl. G01R 31/36

(52) U.S. Cl. CPC G01R 31/3606
USPC 324/434

(57) ABSTRACT

In a battery monitoring system, an input current flowing through an input portion of an isolator member is larger than an output current flowing through an output portion of the isolator member. The output portion is electrically isolated from the input portion. The input and output portions of the isolator member are connected respectively to first and second circuits included in a group of the control circuit and the plurality of monitoring circuits. The first and second circuits are selected for the isolator member, The first and second circuits respectively serve as a sender and a receiver. The isolator member transfers serial data sent from the sender to the receiver while the sender and the receiver are electrically isolated from each other. The isolator is mounted on a substrate included in the control and monitoring substrates. The receiver is mounted on the substrate.

### CROSS REFERENCE TO RELATED APPLICATIONS

This application is based on and claims the benefit of priority from Japanese Patent Application 2013-216131 filed on Oct. 17, 2013, the disclosure of which is incorporated in its entirety herein by reference.

### TECHNICAL FIELD

The present disclosure relates to systems for monitoring the state of at least one battery pack comprised of a plurality of cells.

### BACKGROUND

There are known chargeable high-voltage batteries, each of which is designed as a battery pack; the battery pack is comprised of a plurality of cells connected in series. Repeated charging and discharging of such a high-voltage battery cause variations in deterioration of the cells. In order to accurately know the variations, there are known systems to monitor the state of each cell of the battery pack, and protect each cell based on the monitored results. An example of the systems is disclosed in Japanese Patent Application Publication No. 2012-83123, referred to as a patent publication.

The system disclosed in the patent publication includes: a plurality of battery packs each of which is comprised of series-connected cells; and a plurality of battery ECUs provided for the respective battery packs. Each of the battery ECUs is operative to measure:
a voltage across each of the cells included in a corresponding one of the battery packs; and
a current flowing through each of the cells included in a corresponding one of the battery packs.

The battery ECUs are communicably coupled to each other via CAN (Controller Area Network) buses. One of the battery ECUs serves as a master ECU. The master ECU is operative to receive, via the CAN buses, the voltage and current for each of the cells measured by the corresponding battery ECU, and operative to determine whether there is an abnormality in each of the cells based on the voltage and current measured for the corresponding cell.

### SUMMARY

As described above, the battery ECUs are communicably coupled to each other via the CAN buses. Because each of the CAN buses is designed using twisted pair cables, each of the CAN buses has a superior resistance against noise.

However, using the CAN buses causes each of the battery ECUs to include expensive components required to communicate data with another battery ECU via the CAN buses; these expensive components include a CAN microcomputer incorporating therein a CAN communications controller, a transceiver IC, and other electrical components. This may result in an increase of the number of components in the system and an increase of the manufacturing cost of the system.

In view of the circumstances set forth above, one aspect of the present disclosure seeks to provide systems for monitoring the state of a battery pack comprised of series-connected cells, each of which is designed to address the problem set forth above.

Specifically, an alternative aspect of the present disclosure aims to provide such systems, each of which has improved resistance against noise while reducing the number of components and the manufacturing cost as compared with the conventional system; the conventional system is comprised of a plurality of battery ECUs communicably coupled to each other via CAN buses.

According to an exemplary aspect of the present disclosure, there is provided a system for monitoring at least one of a state of a battery pack comprising a plurality of cells; and a state of the plurality of cells. The system includes a control circuit that controls the battery pack, a control substrate on which the control circuit is mounted, and a plurality of monitoring circuits. Each of the plurality of monitoring circuits monitors a physical parameter indicative of the at least one of the state of the battery pack and the state of the plurality of cells, and sends the physical parameter to the control circuit. The control circuit receives the physical parameter sent from each of the plurality of monitoring circuits, and sends a control instruction based on the physical parameter to at least one of the plurality of monitoring circuits. The system includes a plurality of monitoring substrates on which the respective monitoring circuits are mounted, and an isolator member having an input portion and an output portion. The input portion and output portion are configured such that an input current flowing through the input portion is larger than an output current flowing through the output portion. The output portion is electrically isolated from the input portion.

The input portion and the output portion of the isolator member are connected respectively to a first circuit and a second circuit included in a group of the control circuit and the plurality of monitoring circuits. The first circuit and the second circuit are selected for the isolator member,

The first circuit serves as a sender, the second circuit serves as a receiver, and the isolator member transfers serial data sent from the sender to the receiver while the sender is electrically isolated from the receiver. The isolator member is mounted on a substrate included in the control and monitoring substrates, and the receiver is mounted on the substrate included in the control and monitoring substrates.

In the system according to the exemplary aspect, the isolator member transfers serial data sent from the sender to the receiver while the sender and the receiver are electrically isolated from each other.

Specifically, the isolator member enables serial communications between the sender and the receiver, i.e. the first and second circuits, included in the group of the control circuit and the plurality of monitoring circuits without additional elements, such as CAN transceivers required for CAN communications. This results in reduction of the number of electrical components of the battery monitoring system;
the areas of the substrates in which the communications devices including the isolator member, are installed; and
the manufacturing cost of the battery monitoring system as compared with those of a conventional battery monitoring system using CAN communications between each pair of different circuits.

In addition, the isolator member has the input portion and the output portion such that an input current flowing through the input portion is larger than an output current flowing through the output portion.

The isolator member is mounted on a substrate included in the control and monitoring substrates, and the receiver is mounted on the substrate included in the control and monitoring substrates.

Thus, a large amount of the input current is required to be sent from the sender to the input portion of the isolator member as compared with an amount of the output current flowing through the output portion of the isolator member during serial communications. In addition, the isolator member is mounted on the substrate on which the receiver is mounted. Thus, the length of wires connecting between the substrate on which the sender is mounted and the substrate on which the isolator member is mounted is longer than that of wires connecting between the same substrate in which the isolator member and the receiver are commonly installed.

Usually, the longer the length of a wire is, the more noise can enter the wire, and noise can affect wires connecting between different substrates. In view of the circumstances, the battery monitoring system is configured such that a large amount of the input current flows through the input portion of the isolator member, i.e. through the wires connected between the sender-side substrate and the input portion of the isolator member of the receiver-side substrate. This configuration results in an improvement of resistance against noise, thus limiting noise generated in the sender-side substrate from being transferred to the receiver-side substrate.

The isolator member according to the exemplary aspect electrically isolates the sender and receiver from each other. Thus, it is possible for the isolator member to perform serial communications between the sender and the receiver even if a ground portion of the sender-side substrate and that of the receiver-side substrate are separated from each other, and the reference potentials of the ground portions are different from each other.

In a preferred embodiment, the isolator includes a photocoupler. Because the input portion of the photocoupler is a photodiode and the output portion is a phototransistor, there is no need of a power supply for the input portion of the photocoupler. That is, there is an elimination of power-supply wires connecting between the sender and the input portion of the photocoupler as compared with a case where the photocoupler is mounted in the sender-side substrate.

Various aspects of the present disclosure can include and/or exclude different features, and/or advantages where applicable. In addition, various aspects of the present disclosure can combine one or more feature of other embodiments where applicable. The descriptions of features, and/or advantages of particular embodiments should not be construed as limiting other embodiments or the claims.

### BRIEF DESCRIPTION OF THE DRAWINGS

Other aspects of the present disclosure will become apparent from the following description of embodiments with reference to the accompanying drawings in which:

FIG. 1 is a block diagram schematically illustrating an example of the configuration of a battery monitoring system according to a first embodiment of the present disclosure;

FIG. 2 is a flowchart schematically illustrating an example of a voltage monitoring routine carried out by the battery monitoring system illustrated in FIG. 1;

FIG. 3 is a block diagram schematically illustrating an example of the configuration of a battery monitoring system according to a second embodiment of the present disclosure; and

FIG. 4 is a flowchart schematically illustrating an example of a voltage monitoring routine carried out by the battery monitoring system illustrated in FIG. 3.

### DETAILED DESCRIPTION OF EMBODIMENT

Embodiments of the present disclosure will be described hereinafter with reference to the accompanying drawings. In the drawings, identical reference characters are utilized to identify identical corresponding components.

### First Embodiment

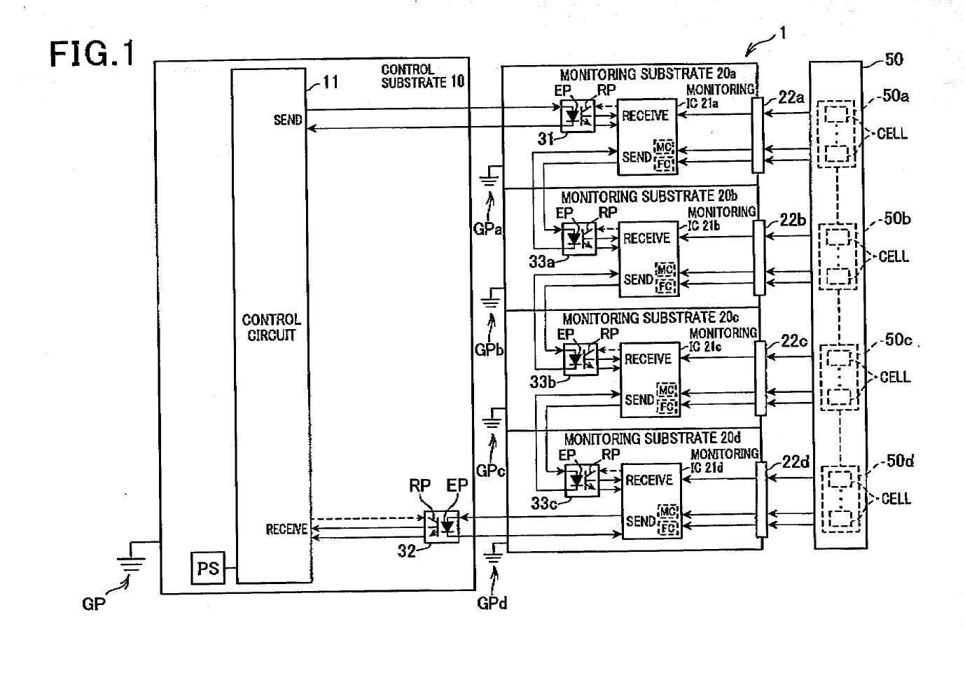

Referring to FIG. 1, there is illustrated a system 1 for monitoring the state of battery packs according to a first embodiment of the present invention. The system 1, referred to as a battery monitoring system 1, includes a control substrate, i.e. a control circuit board, 10, a control circuit 11, and a plurality of, such as four, monitoring substrates 20a, 20b, 20c, and 20d. The battery monitoring system 1 also includes photocouplers 31, 32, 33a, 33b, and 33c serving as isolators. The battery monitoring system 1 is operative to monitor the state of a battery 50. In FIG. 1, solid arrows represent connection wires, and dashed arrows represent wires for supplying operating power to each of the photocouplers 31, 32, 33a, 33b, and 33c.

The battery SO is, for example, a high-voltage battery comprised of a plurality of battery packs connected in series. Each of the series-connected battery packs is comprised of a plurality of cells connected in series. A lithium-ion secondary battery is for example used as the battery 50. For example, in the first embodiment, the battery 50 is comprised of four series-connected battery packs 50a, 50b, 50c, and 50d, so that the monitoring substrates 20a-20d are provided for the respective battery packs 50a-50d.

The battery monitoring system 1 also includes monitoring ICs (Integrated Circuits) 21a, 21b, 21c, and 21d, and equalizers 22a, 22b, 22c, and 22d. The photocoupler 31, monitor IC 21a, and equalizer 22a are mounted in the monitoring substrate 20a, and the photocoupler 33a, monitor IC 21b, and equalizer 22b are mounted in the monitoring substrate 20b. The photocouplers 33b and 33c, the monitor ICs 21c and 21d, and the equalizers 22c and 22d are also mounted in the respective monitoring substrates 20c and 20d.

Note that, in the first embodiment, A is mounted, installed, or another similar expression on or in B represents that A is mounted, installed, or another similar expression on and/or in B.

Each of the monitoring substrates 20a, 20b, 20c, and 20d serves as a high-voltage portion having a predetermined ground portion and a predetermined higher potential relative to the ground based on a power-supply voltage supplied from the battery 50.

In the first embodiment, a ground portion GP of the control substrate 10 is separated from ground portions GPa to GPd of the monitoring substrates 20a to 20d, and the ground portions GPa to GPd of the monitoring substrates 20a to 20d are separated from each other. The reference potentials, i.e. the ground potentials, of the ground portions GPa, GPb, GPc, and GPd of the respective monitoring substrates 20a, 20b, 20c, and 20d can be different from each other, or can be identical to each other.

Each of the monitoring ICs 21a to 21d is comprised of for example, a multiplexer circuit MC and a flying-capacitor circuit FC, and is operative to monitor the state of each cell, i.e. the voltage across each cell, of a corresponding one of the battery packs 50a to 50d. The structure and operations of the multiplexer circuit MC and the flying-capacitor circuit FC of the monitoring IC 21a will be described hereinafter.

The multiplexer circuit MC includes a plurality of positive switches and a plurality of negative switches. Each of the positive switches is connected between the positive terminal of a corresponding one of the plurality of cells of the corresponding battery pack 50a and the flying-capacitor circuit FC. Each of the negative switches is connected between the negative terminal of a corresponding one of the plurality of cells of the corresponding battery pack 50a. and the flying-capacitor circuit FC.

Specifically, the multiplexer circuit MC is operative to selectively turn on the positive switch for a target cell of the battery pack 50a and the negative switch for the target cell. This connects the target cell of the battery pack 50a to the flying-capacitor circuit FC.

The flying-capacitor circuit FC includes a flying capacitor, and is configured such that, when the positive and negative switches for the target cell are turned on, the voltage across the target cell is charged in the flying capacitor. The flying-capacitor circuit FC is operative to measure the voltage charged in the flying capacitor as the voltage across the target cell.

Specifically, the multiplexer circuit MC sequentially switches selection of a cell of the battery pack 50a as a target cell until all cells of the battery pack 50a have been selected. This results in the respective voltages across all the cells of the battery pack 50a having been measured sequentially by the multiplexer circuit MC. That is, the monitor IC 21a is operative to monitor the respective voltages across all the cells included in the battery pack 50a based on the respective measured voltages across all the cells of the battery pack 50a.

The structure and operations of each of the other monitoring ICs 21b to 21d are identical to those of the monitoring IC 21a. Thus, each of the monitoring ICs 21b to 21d is operative to monitor the respective voltages across all the cells included in a corresponding one of the battery packs 50b to 50d based on the respective measured voltages across all the cells included in a corresponding one of the battery packs 50b to 50d.

Each of the equalizers 22a to 22d is composed of, for example, a plurality of discharging switches.

The structure and operations of the equaliser 22a will be described hereinafter. Each of the discharging switches of the equalizer 22a is connected between the positive terminal and the negative terminal of a corresponding one of the plurality of cells of the corresponding battery pack 50a. Each of the discharging switches of the equalizer 22a is individually turned on or off according to instructions sent from the control circuit 11. Each of the discharging switches of the equalizer 22a normally has an off state, i.e. an open state.

Specifically, when a voltage across a cell of the battery pack 50a becomes equal to or higher than a predetermined upper threshold, a control instruction is sent from the control circuit 11 to a switch of the equalizer 22 corresponding to the cell, the switch is switched from the off state to an on state. This short-circuits the positive and negative terminals of the cell to discharge the cell, thus reducing the voltage across the cell to be close to the voltages across the other cells of the battery pack 50a.

The structure and operations of each of the other equalizers 22b-22d are identical to those of the equalizer 22a. Thus, the equalizers 22a to 22d are operative to equalize the voltages across the respective cells of the battery packs 50a to 50d to each other under control of the control circuit 11.

The control circuit 11 is mounted on the control substrate 10. For example, the control circuit 11 is designed as a microcomputer equipped with at least CPU, a memory, and an I/O interface; the CPU, memory, and the I/O interface are communicable with each other. The control circuit 11, i.e. the CPU, is operative to execute predetermined functions M accordance with programs stored in the memory. The control substrate 10 is connected to a power source PS, so that the control substrate 10 has a predetermined lower potential based on a power-supply voltage supplied from the power source PS. Because the lower potential at the control substrate 10 is lower than that at each of the monitoring substrates 20a to 20d, the control substrate 10 serves as a low-voltage portion.

For example, the control circuit 11 is operative to send, to the monitoring IC 21 a, a voltage sending instruction to at least one of the monitoring ICs 21a to 21d. The voltage sending instruction instructs a monitoring IC to send the voltages across the respective cells included in a corresponding battery pack.

When the voltages across the respective cells included in each of the battery packs 50a to 50d are sent from a corresponding one of the monitoring ICs 21a to 21d, the control circuit 11 is operative to receive the voltages across the respective cells included in each of the battery packs 50a to 50d.

Then, the control circuit 11 is operative to:

compare the voltages across the respective cells included in each of the battery packs 50a to 50d with each other for each battery pack; and

determine, based on the results of the comparison, whether there are one or more cells included in at least one battery pack; the one or more cells are required to be discharged for voltage equalization.

Upon determination that at least one cell included in at least one battery pack is required to be discharged, the control circuit 11 is operative to send a control instruction for the at least one battery pack to, for example, the monitoring IC 21a as a representative monitoring IC. The control instruction for the at least one battery pack is designed to:

include data specifying the at least one battery pack, and the at least one cell required to be discharged included in the at least one battery pack, and data specifying a discharging period; and

instruct the corresponding at least one equalizer to discharge the at least one cell for the specified discharging period.

How data is communicated between the control circuit 11 and the monitoring ICs 21a to 21d will be described in detail later.

The photocoupler 31, serving as a first isolator, is mounted on the monitoring substrate 20a, and configured to communicably connect between the monitoring IC 21a and the control circuit 11 while isolating the monitoring IC 21a and the control circuit 11 from each other. That is, the control circuit 11 and the monitoring IC 21a are selected for the photocoupler 31.

Specifically, the photocoupler 31 is comprised of a light-emitting portion, such as a light-emitting diode, EP having a first resistance. The light-emitting portion 31a serves as an input portion connected to the control circuit 11 via wires. The photocoupler 31 is also comprised of a light-receiving portion, such as a phototransistor, RP having a second resistance lower than the first resistance. The light-receiving portion RP serves as an output portion, connected to the monitoring IC 21a via wires. A drive voltage required for cause an input current to flow through the light-emitting portion EP of the photocoupler 31 and a drive voltage required for an output current to flow through the light-receiving portion RP of the photocoupler 31 can be equal to or different from each other. The drive voltages and the first and second resistances are set such that the input current flowing through the light-emitting portion EP of the photocoupler 31 is larger than the output current flowing through the light-receiving portion RP of the photocoupler 31.

For example, when a sender, i.e. the control circuit 11, sends a pulse signal, i.e. a pulse current, as an instruction through the light-emitting diode EP of the photocoupler 31, the light-emitting diode EP emits pulsed light. The light-reflective portion RP of the photocoupler 31 receives the pulsed light to turn on, thus outputting, to a receiver, i.e. the monitoring IC 21a, a pulse signal matching with the pulse signal sent from the sender 11. This results in transfer of the pulse signal from the control circuit 11 to the monitoring IC 21a. For example, an on state of the pulse signal corresponds to a bit value of 1, and an off state of the pulse signal corresponds to a bit value of 0.

Thus, the light-emitting portion EP and the light-receiving portion RP of the photocoupler 31 serve to relay electrical data, for example, pulse signals, sent from the control circuit 11 optically to the monitoring IC 21a while isolating the control circuit 11 and the monitoring IC 21a from each other.

Between the control circuit 11 and the monitoring IC 21a, the control circuit 11 serves as a sender to send, via the photocoupler 31, serial data to the monitoring IC 21a, and the monitoring IC 21a serves as a receiver to receive the serial data. The serial data sent from the control IC 11 has one bit of data transmitted at a time.

The photocoupler 32, serving as a second isolator, is mounted on the control substrate 10, and configured to communicably connect between the monitoring IC 21d and the control circuit 11 while isolating the monitoring IC 21d and the control circuit 11 from each other. That is, the monitoring IC 21d and the control circuit 11 are selected for the photocoupler 32.

Specifically, the photocoupler 32 is comprised of a light-emitting portion, such as a light-emitting diode, EP having the first resistance. The light-emitting portion EP serves as an input portion connected to the monitoring IC 21 d via wires. The photocoupler 32 is also comprised of a light-receiving portion, such as a phototransistor, RP having the second resistance lower than the first resistance. The light-receiving portion RP serves as an output portion, connected to the control circuit 11 via wires. How the light-emitting portion EP and the light-receiving portion RP of the photocoupler 32 operate is identical to how the light-emitting portion EP and the light-receiving portion RP of the photocoupler 31 operate described above.

That is, the light-emitting portion EP and the light-receiving portion RP of the photocoupler 32 serve to relay electrical data, i.e. electrical signals, sent from the monitoring IC 21d optically to the control circuit 11 while electrically isolating the control circuit 11 and the monitoring IC 21d from each other.

Between the monitoring IC 21d and the control circuit 11, the monitoring IC 21d serves as a sender to send, via the photocoupler 32, serial data to the control circuit 11, and the control circuit 11 serves as a receiver to receive the serial data. The serial data sent from the monitoring IC 21d is transmitted one bit at a time.

Specifically, the photocouplers 31 and 32 enable serial communications between the control IC 11 serving as the low-voltage portion and the monitoring ICs 21a and 21d serving as part of the high-voltage portion while isolating the low-voltage portion and the high-voltage portion from each other.

The photocoupler 33a, serving as one of third isolators, is mounted on the monitoring substrate 20b, and configured to communicably connect between the monitoring ICs 21a and 21b while isolating the monitoring ICs 21a and 21b from each other. That is, the monitoring IC 21a and the monitoring IC 21b are selected for the photocoupler 33a.

Specifically, the photocoupler 33a is comprised of a light-emitting portion, such as a light-emitting diode, EP having the first resistance. The light-emitting portion EP serves as an input portion connected to the monitoring IC 21a via wires. The photocoupler 33a is also comprised of a light-receiving portion, such as a phototransistor, RP having the second resistance lower than the first resistance. The light-receiving portion RP serves as an output portion, connected to the monitoring IC 21b via wires. How the light-emitting portion EP and the light-receiving portion RP of the photocoupler 33a operate is identical to how the light-emitting portion EP and the light-receiving portion RP of the photocoupler 31 operate described above.

That is, the light-emitting portion EP and the light-receiving portion RP of the photocoupler 33a serve to relay electrical data, i.e. electrical signals, sent from the monitoring IC 21a optically to the monitoring IC 21b while electrically isolating the monitoring ICs 21a and 21b from each other.

Between the monitoring ICs 21a and 21b, the monitoring IC 21a serves as a sender to send, via the photocoupler 33a, serial data to the monitoring IC 21b, and the monitoring IC 21b serves as a receiver to receive the serial data. The serial data sent from the monitoring IC 21a is transmitted one bit at a time.

The photocoupler 33b, serving as one of the third isolators, is mounted on the monitoring substrate 20c, and configured to communicably connect between the monitoring ICs 21b and 21c while isolating the monitoring ICs 21b and 21c from each other. That is, the monitoring IC 21b and the monitoring IC 21c are selected for the photocoupler 33b.

Specifically, the photocoupler 33b is comprised of a light-emitting portion, such as a light-emitting diode, EP having the first resistance. The light-emitting portion EP serves as an input portion connected to the monitoring IC 21b via wires. The photocoupler 33b is also comprised of a light-receiving portion, such as a phototransistor, RP having the second resistance lower than the first resistance. The light-receiving portion RP serves as an output portion connected to the monitoring IC 21c via wires. How the light-emitting portion EP and the light-receiving portion RP of the photocoupler 33b operate is identical to how the light-emitting portion EP and the light-receiving portion RP of the photocoupler 31 operate described above.

That is, the light-emitting portion EP and the light-receiving portion RP of the photocoupler 33b serve to relay electrical data, i.e. electrical signals, sent from the monitoring IC 21b optically to the monitoring IC 21c while electrically isolating the monitoring ICs 2 lb and 21c from each other.

Between the monitoring ICs 21b and 21c, the monitoring IC 21b serves as a sender to send, via the photocoupler 33b, serial data, which is indicative of measured data, to the monitoring IC 21c, and the monitoring IC 21c serves as a receiver to receive the serial data. The serial data sent from the monitoring IC 21b is transmitted one bit at a time.

The photocoupler 33c, serving as one of the third isolators, is mounted on the monitoring substrate 20d, and configured to communicably connect between the monitoring ICs 21c and 21d while isolating the monitoring ICs 21c and 21d from each other. That is, the monitoring IC 21c and the monitoring IC 21d are selected for the photocoupler 33e.

Specifically, the photocoupler 33c is comprised of a light-emitting portion, such as a light-emitting diode, EP having the first resistance. The light-emitting portion EP serves as an input portion connected to the monitoring IC 21c via wires. The photocoupler 33c is also comprised of a light-receiving portion, such as a phototransistor RP having the second resistance lower than the first resistance. The light-receiving portion RP serves as an output portion connected to the monitoring IC 21d via wires.

How the light-emitting portion EP and the light-receiving portion RP of the photocoupler 33c operate is identical to how the light-emitting portion EP and the light-receiving portion RP of the photocoupler 31 operate described above.

That is, the light-emitting portion EP and the light-receiving portion RP of the photocoupler 33c serve to relay electrical data, i.e. electrical signals, sent from the monitoring IC 21c optically to the monitoring IC 21d while electrically isolating the monitoring ICs 21c and 21d from each other.

Between the monitoring ICs 21c and 21d, the monitoring IC 21c serves as a sender to send, via the photocoupler 33c, serial data, which is indicative of measured data, to the monitoring IC 21d, and the monitoring IC 21d serves as a receiver to receive the serial data. The serial data sent from the monitoring IC 21c represents that one bit of the data is transmitted at a time.

In other words, the monitoring ICs 21a to 21d are sequentially communicable in this order via the photocouplers 33a to 33c.

Thus, the battery monitoring system 1 according to the first embodiment provides an electrically-isolated ring communication route, i.e. an electrically-isolated circulative route, constructed by the photocouplers 31, 32, and 33a to 33d among the monitoring ICs 21a to 21d installed in the respective monitoring substrates 20a to 20d and the control circuit 11 installed in the control substrate 10.

The photocoupler 31, which communicably couples between the control circuit 11 and the monitoring IC 21a, is installed in the monitoring substrate 20a. In the monitoring substrate 20a, the monitoring IC 21a serving as the receiver between the control circuit 11 and the monitoring IC 21a is installed.

The photocoupler 32, which communicably couples between the monitoring IC 21d and the control circuit 11, is installed in the control substrate 10. In the control substrate 10, the control circuit 11 serving as the receiver between the monitoring IC 21d and the control circuit 11 is installed.

The photocoupler 33a, which communicably couples between the monitoring ICs 21a and 21b, is installed in the monitoring substrate 20b. In the monitoring substrate 20b, the monitoring IC 21b serving as the receiver between the monitoring ICs 21a and 21b is installed.

The photocoupler 33b, which communicably couples between the monitoring ICs 21b and 21c, is installed in the monitoring substrate 20c. In the monitoring substrate 20c, the monitoring IC 21c serving as the receiver between the monitoring ICs 21b and 21c is installed.

The photocoupler 33c, which communicably couples between the monitoring ICs 21c and 21d, is installed in the monitoring substrate 20d. In the monitoring substrate 20d, the monitoring IC 21d serving as the receiver between the monitoring ICs 21c and 21d is installed.

That is, let us assume that:

the wires connecting between each of the senders (11, 21d, 21a, 21b, and 21c) and a corresponding one of the photocouplers 31, 32, 33a, 33b, and 33c) via corresponding different substrates are referred to as sender wires; and

the wires connecting between each of the photocouplers 31, 32, 33a, 33b, and 33c) and a corresponding one of the receivers (21a, 32, 21b, 21c, and 21d) in a corresponding one substrate are referred to as receiver wires.

In this assumption, the sender wires are longer in length than the receiver wires because the sender wires are located via corresponding different substrates. It is known that a large amount of current flows through the sender wires as compared with an amount of current flowing through the receiver wires. This results in an improvement of resistance against noise.

The input portion, i.e. the light-emitting diode, of each of the photocouplers 31, 32, and 33a to 33c operates without operating voltages, but the output portion, i.e. the phototransistor, of each of the photocouplers 31, 32, and 33a to 33c operates only when an operating voltage is supplied thereto. In view of the characteristics, as described above, each of the photocouplers 31, 32, 33a, 33b, and 33d is installed in a corresponding one of the receiver substrates in which a corresponding receiver is installed, so that the phototransistor operates based on an operating voltage supplied from the corresponding receiver substrate. This avoids the need for power-supply wires connecting between the phototransistors of the photocouplers installed in the respective receiver substrates and the substrates in which the corresponding senders are installed.

Next, operations of the power supply system 1 will be described hereinafter.

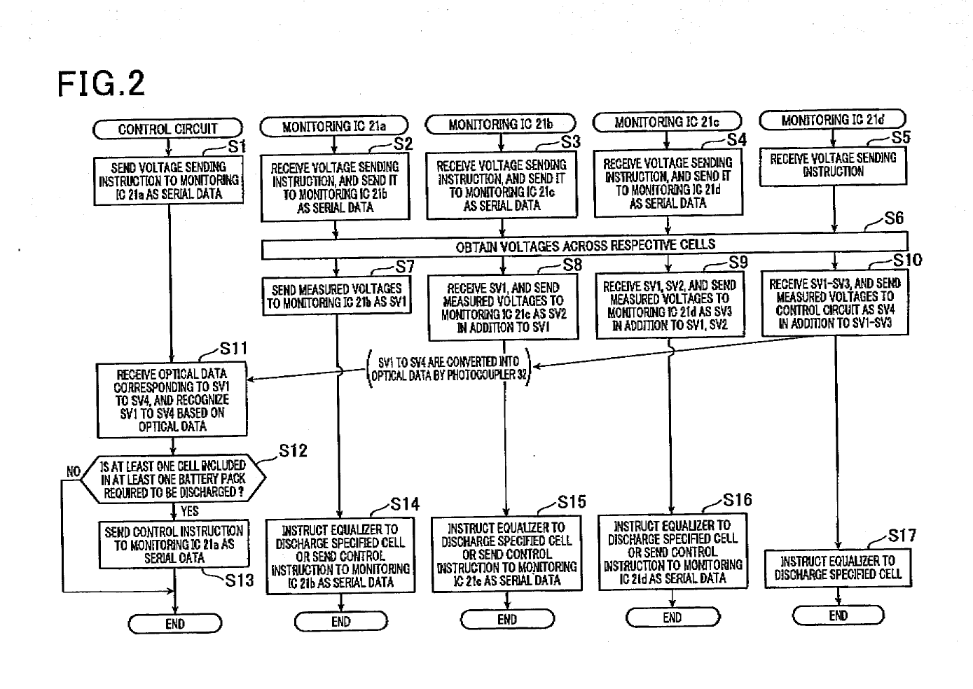

FIG. 2 schematically illustrates a voltage monitoring routine cyclically carried out by the power supply system 1.

When starting the voltage monitoring routine, the control circuit 11 sends the voltage sending instruction to the monitoring IC 21a via the photocoupler 31 as serial data in step Si of a flowchart illustrated in FIG. 2. The monitoring IC 21a receives the voltage sending instruction, and sends the voltage sending instruction to the monitoring IC 21b via the photocoupler 33a as serial data in step S2.

When receiving the voltage sending instruction, the monitoring IC 2 lb sends the voltage sending instruction to the monitoring IC 21c via the photocoupler 33b as serial data in step S3. When receiving the voltage sending instruction in step S4, the monitoring IC 21c sends the voltage sending instruction to the monitoring IC 21d via the photocoupler 33c as serial data in step S4, so that the monitoring IC 21d receives the voltage sending instruction in step S5.

That is, the electrically-isolated ring communication route causes the voltage sending instruction to sequentially send to the monitoring IC 21a, the monitoring IC 21b, the monitoring IC 21c, and the monitoring IC 21d.

When receiving the voltage sending instruction, each of the monitoring ICs 21a to 21d obtains the voltages across the respective cells included in a corresponding one of the battery packs 50a to 50d in step S6. Then, the monitoring IC 21a sends the voltages across the respective cells included in the battery pack 50a to the monitoring IC 21b via the photocoupler 33a as first serial voltage data (referred to as SV1 in FIG. 2) of the battery pack 50a in step S7.

When receiving the first serial voltage data of the battery pack 50a, the monitoring IC 21b receives the first serial voltage data of the battery pack 50a in step S8. Then, the monitoring IC 21b sends, in addition to the first serial voltage data of the battery pack 50a, the voltages across the respective cells included in the battery pack 50b to the monitoring IC 21c via the photocoupler 33b as second serial voltage data (referred to as SV2 in FIG. 2) of the battery pack 50b in step S8.

The monitoring IC 21c receives the first serial voltage data and the second serial voltage data of the battery packs 50a and 50b in step S9. Then, the monitoring IC 21c sends, in addition to the first serial voltage data and second serial voltage data of the battery packs 50a and 50b, the voltages across the respective cells included in the battery pack 30c to the monitoring IC 21d via the photocoupler 33b as third serial voltage data (referred to as SV3 in FIG. 2) of the battery pack 50c in step S9.

The monitoring IC 21d receives the first serial voltage data, second serial voltage data, and third serial voltage data of the battery packs 50a, 50b, and 50c in step S10.

Then, the monitoring IC 21d sends, in addition to the first serial voltage data, second serial voltage data, and third serial voltage data of the battery packs 50a, 50b, and 50c, the voltages across the respective cells included in the battery pack 50d to the control circuit 11 as fourth serial voltage data of the battery pack 50d in step S10.

The first serial voltage data, second serial voltage data, third serial voltage data, and fourth serial voltage data are received by the photocoupler 32. Then, optical data corresponding to the first serial voltage data, second serial voltage data, third serial voltage data, and fourth serial voltage data is sent from the photocoupler 32 to the control circuit 11.

When the optical data is sent from the monitoring IC 21d to the control circuit 11 via the photocoupler 32, the control circuit 11 receives the optical data, and recognizes the first serial voltage data, second serial voltage data, third serial voltage data, and fourth serial voltage data based on the received optical data in step S11. Then, the control circuit 11 compares the voltages across the respective cells included in each of the battery packs 50a to 50d with each other for each battery pack in step S12. Then, the control circuit 11 determines, based on the results of the comparison, whether there is at least one cell included in at least one battery pack; the at least one cell is required to be discharged for voltage equalization in step S12.

Upon determination that at least one cell included in at least one battery pack is required to be discharged (YES in step S12), the control circuit 11 sends a control instruction for the at least one battery pack to the monitoring IC 21a via the photocoupler 31 as serial data in step S13. The control instruction includes: data specifying the at least one battery pack, and the at least one cell required to be discharged included in the at least one battery pack; and data specifying a discharging period.

When receiving the control instruction sent from the control circuit 11, the monitoring IC 21a:

instructs the equalizer 22a to discharge the at least one cell for the specified discharging period if the control instruction specifies the monitoring IC 21a, or

sends the control instruction to the monitoring IC 21b via the photocoupler 33a as serial data if the control instruction specifies one of the monitoring ICs 21b, 21c, and 21d in step S14.

After completion of the operation in step S14, the monitoring IC 21a terminates the voltage monitoring routine.

When receiving the control instruction sent from the monitoring IC 21a, the monitoring IC 21b:

instructs the equalizer 22b to discharge the at least one cell for the specified discharging period if the control instruction specifies the monitoring IC 21b; or

sends the control instruction to the monitoring IC 21c via the photocoupler 33b as serial data if the control instruction specifies one of the monitoring ICs 21c and 21d in step S15.

After completion of the operation in step S15, the monitoring IC 21a terminates the voltage monitoring routine.

When receiving the control instruction sent from the monitoring IC 21b, the monitoring IC 21c:

instructs the equalizer 22c to discharge the at least one cell for the specified discharging period if the control instruction specifies the monitoring IC 21c; or

sends the control instruction to the monitoring IC 21d via the photocoupler 33c as serial data if the control instruction specifies the monitoring IC 21d in step S16.

After completion of the operation in step S16, the monitoring IC 21a terminates the voltage monitoring routine.

When receiving the control instruction sent from the monitoring IC 21c, the monitoring IC 21d instructs the equalizer 22d to discharge the at least one cell for the specified discharging period in step S17.

After completion of the operation in step S17, the voltage monitoring routine is terminated.

Otherwise, upon determination that no cells included in all the battery packs are required to be discharged (NO in step S12), the voltage monitoring routine is terminated.

As described above, the battery monitoring system 1 is configured such that:

the photocoupler 31 enables serial communications between one pair of different circuits, i.e. the monitoring IC 21a and the control circuit 11, while isolating the monitoring IC 21a and the control circuit 11 from each other;

the photocoupler 32 enables serial communications between one pair of different circuits, i.e. the monitoring IC 21d and the control circuit 11, while isolating the monitoring IC 21d and the control circuit 11 from each other;

the photocoupler 33a enables serial communications between one pair of different circuits, i.e. the monitoring les 21a and 21b, while isolating the monitoring ICs 21a and 21b from each other;

the photocoupler 33b enables serial communications between one pair of different circuits, i.e. the monitoring ICs 21b and 21c, while isolating the monitoring ICs 21b and 21c from each other; and the photocoupler 33c enables serial communications between one pair of different circuits, i.e. the monitoring ICs 21c and 21d, while isolating the monitoring ICs 21c and 21d from each other.

This configuration makes it possible for each pair of different circuits to communicate serial data with each other via a corresponding photocoupler with each other without additional electrical components except for the corresponding photocoupler. This results in reduction of the number of electrical components of the battery monitoring system 1;

the areas of the substrates in which the communications devices, i.e. photocouplers, are installed; and

the manufacturing cost of the battery monitoring system 1 as compared with those of a conventional battery monitoring system using CAN communications between each pair of different circuits.

In the battery monitoring system 1, each of the photocouplers, which communicably couples between a corresponding one pair of a sender and a receiver, is installed in the substrate incorporating therein the receiver. For example, the photocoupler 31, which communicably couples between the control circuit 11 serving as a sender and the monitoring IC 21a serving as a receiver, is installed in the monitoring substrate 20a; the monitoring substrate 20a incorporates therein the monitoring IC 21a. As another example, the photocoupler 33b, which communicably couples between the monitoring IC 21b serving as a sender and the monitoring IC 21c serving as a receiver, is installed in the monitoring substrate 20c; the monitoring substrate 20c incorporates therein the monitoring IC 21c serving as the receiver between the monitoring ICs 21b and 21c.

This configuration makes longer the wires, i.e. sender wires, connecting between the sender and the photocoupler installed in the receiver as compared with the wires, i.e. receiver wires, connecting between the photocoupler and the receiver. Because a large amount of current flows through the sender wires as compared with an amount of current flowing through the receiver wires, the battery monitoring system 1 provides an improvement of resistance against noise. The improvement of resistance against noise makes it possible to limit noise generated in the substrate incorporating therein the sender from being transferred to the substrate incorporating therein the receiver.

The input portion, i.e. the light-emitting diode, of each of the photocouplers 31, 32, and 33a to 33c operates without operating voltages, but the output portion, i.e. the phototransistor, of each of the photocouplers 31, 32, and 33a to 33c operates only when an operating voltage is supplied thereto.

In view of the characteristics, as described above, the battery monitoring system 1 is configured such that each of the photocouplers 31, 32, and 33a to 33d is installed in a corresponding one of the receiver substrates; the receiver substrates incorporates therein a corresponding receiver. This enables the phototransistor of the photocoupler to operate based on an operating voltage supplied from the corresponding receiver substrate.

This avoids any need for power-supply wires connecting between: the phototransistors of the photocouplers 31, 32, 33a, 33b, 33c, and 33d installed in the respective receiver substrates; and the sender substrates in which the corresponding senders are installed.

Each of the photocouplers 31, 32, and 33a to 33d coupling between a corresponding pair of a sender and a receiver enables serial communications between them even if the ground potential of the sender substrate in which the sender is installed is different from that of the receiver substrate in which the receiver is installed.

The photocouplers 31 and 32 enable serial communications between the control IC 11 serving as the low-voltage portion and the monitoring ICs 21a and 21d serving as part of the high-voltage portion while isolating the low-voltage portion and the high-voltage portion from each other. This results in serial communications between the low-voltage portion and the high-voltage portion that are electrically isolated from each other while maintaining, at a lower level, each of:

the number of electrical components of the battery monitoring system 1;

the areas of the substrates in which the communication devices, i.e. the photocouplers, are installed; and

the manufacturing cost of the battery monitoring system 1.

As described above, the battery monitoring system 1 is configured such that each of the photocouplers, which communicably couples between a corresponding one pair of a sender and a receiver, is installed in the substrate incorporating therein the receiver. This configuration maintains at a short value, the length of the wires, i.e. receiver wires, connecting between the photocoupler and the receiver, thus reducing the entering of noise into the receiver wires.

### Second Embodiment

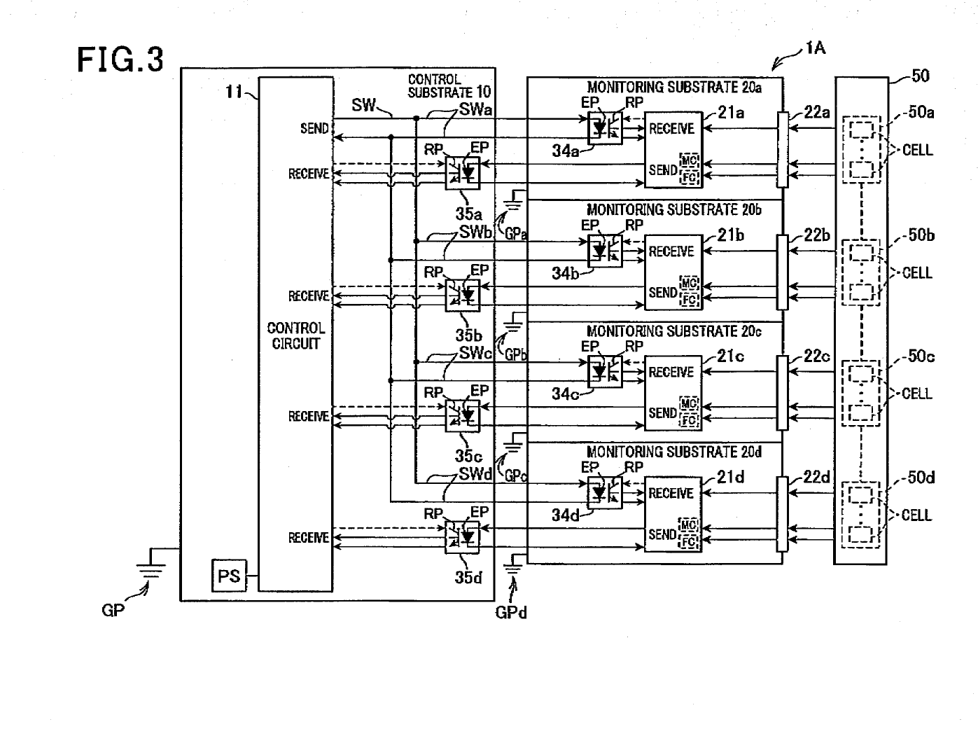

A battery monitoring system 1A according to a second embodiment of the present disclosure will be described with reference to FIG. 3.

The structure and/or functions of the battery monitoring system 1A according to the second embodiment are different from those of the battery monitoring system 1 according to the first embodiment by the following points. So, the different points will be mainly described hereinafter.

The battery monitoring system 1 according to the first embodiment provides the electrically-isolated ring communication route constructed by the photocouplers 31, 32, and 33a to 33d among the monitoring ICs 21a to 21d installed in the respective monitoring substrates 20a to 20d and the control circuit 11 installed in the control substrate 10.

In contrast, the battery monitoring system 1A according to the second embodiment provides an electrically-isolated communication route with another configuration different from the configuration of the electrically-isolated ring communication route.

The battery monitoring system 1A includes photocouplers 34a, 34b, 34c, 34d, 35a, 35b, 35c, and 35d serving as isolators. In FIG. 3, solid arrows represent connection wires, and dashed arrows represent wires for supplying operating power to each of the photocouplers 34a to 34d and 35a. to 35d.

The photocoupler 34a to 34d serving as first isolators are mounted on the respective substrates 20a to 20d. The photocouplers 34a to 34d are configured to communicably connect between the respective monitoring ICs 21a to 21d and the control circuit 11 while isolating the respective monitoring ICs 21a to 21d and the control circuit 11 from each other.

Specifically, each of the photocouplers 34a to 34d is comprised of a light-emitting portion, such as a light-emitting diode, EP having the first resistance. The light-emitting portion EP of each of the photocouplers 34a to 34d serves as an input portion connected to the control circuit 11 via wires. Each of the photocouplers 34a to 34d is also composed of a light-receiving portion, such as a phototransistor, RP having the second resistance lower than the first resistance. The light-receiving portion RP of each of the photocouplers 34a to 34d serves as an output portion, connected to a corresponding one of the monitoring ICs 21a to 21d via wires. How the light-emitting portion EP and the light-receiving portion RP of each of the photocouplers 34a to 34d operate is identical to how the light-emitting portion EP and the light-receiving portion RP of the photocoupler 31 operate described above.

The light-emitting portion EP and the light-receiving portion RP of each of the photocouplers 34a to 34d serve to relay electrical data, i.e. electrical signals, sent from the control circuit 11 optically to a corresponding one of the monitoring ICs 21a to 21d while electrically isolating the control circuit 11 and a corresponding one of the monitoring ICs 21a to 21d from each other.

The photocouplers 35a to 35d serving as second isolators are mounted on the control substrate 10, and are configured to communicably connect between the control circuit 11 and the respective monitoring ICs 21a to 21d while electrically isolating the control circuit 11 and the respective monitoring ICs 21a to 21d from each other.

Specifically, each of the photocouplers 35a to 35d is comprised of a light-emitting portion, such as a light-emitting diode, EP having the first resistance. The light-emitting portion EP of each of the photocouplers 35a to 35d serves as an input portion connected to a corresponding one of the monitoring ICs 21a to 21d via wires. Each of the photocouplers 35a to 35d is also comprised of a light-receiving portion, such as a phototransistor, RP having the second resistance lower than the first resistance. The light-receiving portion RP of each of the photocouplers 35a to 35d serves as an output portion, connected to the control circuit 11 via wires. How the light-emitting portion EP and the light-receiving portion RP of each of the photocouplers 35a to 35d operate is identical to how the light-emitting portion EP and the light-receiving portion RP of the photocoupler 31 operate described above.

The light-emitting portion EP and the light-receiving portion RP of each of the photocouplers 35a to 35d serve to relay electrical data, i.e. electrical signals, sent from a corresponding one of the monitoring ICs 21a to 21d optically to the control circuit 11 while electrically isolating a corresponding one of the monitoring ICs 21a to 21d to the control circuit 11 from each other.

In the second embodiment, a sender wire, a sender line, SW connected to the control circuit 11 branches into four branches SWa to SWd, so that the branches SWa to SWd are connected to the light-emitting portions EP of the respective photocouplers 34a to 34d.

Specifically, the battery monitoring system 1A provides a bus-type transmission route from the control circuit 11 to the monitoring ICs 21a to 21d.

That is, in the bus-type transmission route, the control unit 11 is capable of sending an instruction to the monitoring ICs 21a to 21d at the same timing.

In contrast, the battery monitoring system 1A provides a star-type transmission route from the monitoring ICs 21a to 21d to the control circuit 11. In the star-type transmission route, the monitoring ICs 21a to 21d are capable of independently sending respective data to the control circuit 11.

Each of the photocouplers 34a to 34d communicably couples between the control circuit 11 and a corresponding one of the monitoring ICs 21a to 21d. Each of the photocouplers 34a to 34d is installed in a corresponding one of the substrates 20a to 20d; the corresponding one of the substrates 20a to 20d has installed therein the corresponding monitoring IC that serves as the receiver in the bus-type transmission route.

Similarly, each of the photocouplers 35a to 35d communicably couples between a corresponding one of the monitoring ICs 21a to 21d and the control circuit 11. Each of the photocouplers 35a to 35d is installed in the control substrate 10; the control substrate 10 has installed therein the control circuit 11 that serves as the receiver in the star-type sending routine.

This makes longer the wires, i.e. sender wires, connecting between the sender 11 and a corresponding photocoupler installed in the control substrate for each of the monitoring ICs, i.e. receivers, 21a to 21d in the bus-type transmission route as compared with the wires, i.e. receiver wires, connecting between each of the receivers 21a to 21d and a corresponding photocoupler in the bus-type transmission route.

This also makes longer the sender wires connecting between each of the senders 21a to 21d and a corresponding photocoupler installed in the control substrate 10 for the control circuit 11, i.e. the receiver, in the star-type transmission route as compared with the wires, i.e. receiver wires, connecting between the control circuit 11 and a corresponding photocoupler in the star-type transmission route.

The input portion, i.e. the light-emitting diode, of each of the photocouplers 34a to 34d and 35a to 35d operates without operating voltages, but the output portion, i.e. the phototransistor, of each of the photocouplers 34a to 34d and 35a to 35d operates only when an operating voltage is supplied thereto.

In view of the characteristics, as described above, the battery monitoring system 1A is configured such that:

each of the photocouplers 34a to 34d is installed in a corresponding one of the receiver substrates 20a to 20d incorporating therein a corresponding receiver, i.e. a monitoring IC; and

the photocouplers 35a to 35d are installed in the receiver substrate 10 incorporating therein the receiver, i.e. the control circuit 11.

This enables the phototransistor of each of the photocouplers 34a to 34d and 35a to 35d to operate based on an operating voltage supplied from the corresponding receiver substrate.

This avoids any need for power-supply wires connecting:

between the phototransistors of the photocouplers 34a to 34d installed in the respective receiver substrates, i.e. the monitoring substrates 20a to 20d, and the sender substrate incorporating therein the control circuit 11 serving as the sender; and

between the phototransistors of the photocouplers 35a to 35d installed in the receiver substrate, i.e. the control substrate 10, and each of the sender substrates incorporating therein a corresponding one of the monitoring ICs 21a to 21d serving as the sender.

In the second embodiment, the ground portions GPa to GPd of the monitoring substrates 20a to 20d can be separated from each other or common to each other.

Next, operations of the power supply system 1A will be described hereinafter.

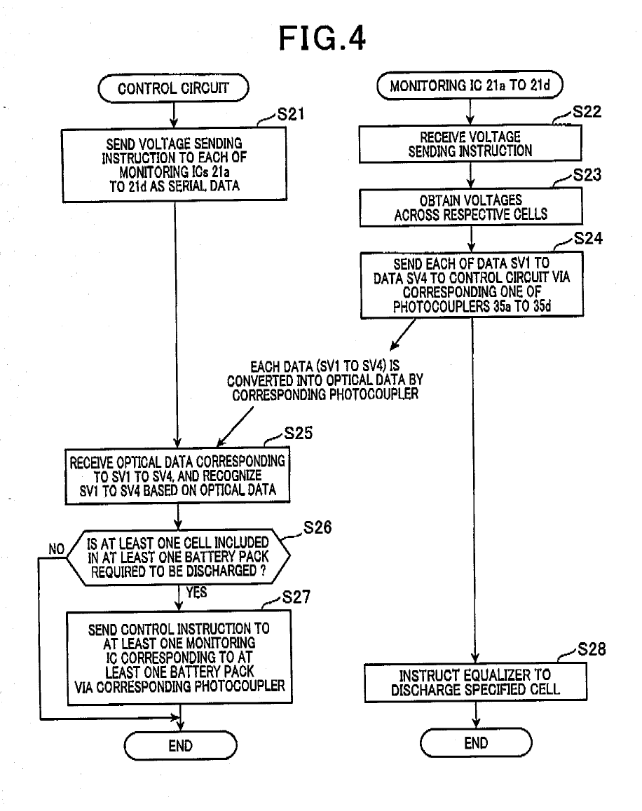

FIG. 4 schematically illustrates a voltage monitoring routine cyclically carried out by the power supply system 1A.

When starting the voltage monitoring routine, the control circuit 11 sends the voltage sending instruction to each of the monitoring ICs 21a to 21d via a corresponding one of the photocouplers 34a to 34d at the same timing as serial data in step S21 of a flowchart illustrated in FIG. 4. Each of the monitoring ICs 21a to 21d receives the voltage sending instruction in step S22, and obtains the voltages across the respective cells included in a corresponding one of the battery packs 50a to 50d in step S23.

Note that the voltages across the respective cells included in the battery pack 50a will be referred to as first serial voltage data (SV1 in FIG. 4) of the battery pack 50a. The voltages across the respective cells included in the battery pack 50b will be referred to as second serial voltage data (SV2 in FIG. 4) of the battery pack 50b. The voltages across the respective cells included in the battery pack 50c will be referred to as third serial voltage data (SV3 in FIG. 4) of the battery pack 50c. The voltages across the respective cells included in the battery pack 50d will be referred to as fourth serial voltage data (SV4 in FIG. 4) of the battery pack 50d.

Then, each of the monitoring ICs 21a to 21d sends a corresponding one of the data SV1, data SV2, data SV3, and data SV4 of the respective battery packs 50a, 50b, 50c, and 50d to the control circuit 11 via a corresponding one of the photocouplers 35a to 35d as serial data in step S24.

The first serial voltage data, second serial voltage data, third serial voltage data, and fourth serial voltage data are received by the photocoupler 32. Then, optical data corresponding to the first serial voltage data, second serial voltage data, third serial voltage data, and fourth serial voltage data is sent from the photocoupler 32 to the control circuit 11.

When the optical data is sent from the photocoupler 32, the control circuit 11 receives the optical data, and recognizes the first serial voltage data, second serial voltage data, third serial voltage data, and fourth serial voltage data based on the received optical data in step S25. Then, the control circuit 11 compares the voltages across the respective cells included in each of the battery packs 50a to 50d with each other for each battery pack in step S26.

Then, the control circuit 11 determine, based on the results of the comparison, whether there is at least one cell included in at least one battery pack; the at least one cell is required to be discharged for voltage equalization in step S26.

Upon determination that at least one cell included in at least one battery pack is required to be discharged (YES in step S26), the control circuit 11 performs operations in the following step S27. Specifically, in step S27, the control circuit 11 sends the control instruction for the at least one battery pack to at least one monitoring IC that corresponds to the at least one battery pack via a corresponding one of the photocouplers 34a to 34d as serial data in step S27.

The control instruction includes: data specifying the at least one battery pack, and the at least one cell required to be discharged included in the at least one battery pack; and data specifying a discharging period.

When receiving the control instruction sent from the control circuit 11, the monitoring IC corresponding to the at least one battery pack instructs the corresponding equalizer to discharge the at least one cell for the specified discharging period in step S28.

After completion of the operation in step S28, the voltage monitoring routine is terminated.

Otherwise, upon determination that no cells included in all the battery packs are required to be discharged (NO in step S26), the voltage monitoring routine is terminated.

As described above, in the battery monitoring system 1A, each of the photocouplers 34a to 34d is installed in a corresponding one of the monitoring substrates 20a to 20d. In each of the monitoring substrates 20a to 20d, a corresponding monitoring IC serving as the receiver in the bus-type sending routine is installed. Each of the photocouplers 34a to 34d enables serial communications between the control circuit 11 and a corresponding one of the monitoring ICs 21a to 21d in the bus-type transmission route without additional electrical components except for the corresponding photocoupler.

In addition, in the battery monitoring system 1A, each of the photocouplers 35a to 35d is installed in the control substrate 10. In the control substrate 10, the control circuit 11 serving as the receiver in the star-type transmission route is installed. Each of the photocouplers 35a to 35d enables serial communications between a corresponding one of the monitoring ICs 21a to 21d and the control circuit 11 in the star-type transmission route without additional electrical components except for the corresponding photocoupler.

Thus, for the same reasons as the battery monitoring system 1 according to the first embodiment, the battery monitoring system 1A results in reduction of:

the number of electrical components of the battery monitoring system 1;

the areas of the substrates in which the communications devices, i.e. the photocouplers, are installed; and

the manufacturing cost of the battery monitoring system 1 as compared with those of a conventional battery monitoring system using CAN communications between each pair of different circuits.

Similarly, the battery monitoring system 1A results in:

improvement of resistance thereof against noise; and

serial communications between the low-voltage portion and the high-voltage portion that are electrically isolated from each other while maintaining, at a lower level, each of: the number of electrical components of the battery monitoring system 1A; and the manufacturing cost of the battery monitoring system 1A.

Particularly, the monitoring ICs 21a to 21d of the battery monitoring system 1A are capable of receiving, at the same timing, an instruction sent from the control unit 11 at the same timing even if the reference potentials, i.e. the ground potentials, of the corresponding substrates 20a to 20d are different form each other. This makes it possible to synchronize the receiving operations of the respective monitoring ICs 21a to 21d, thus improving the controllability of the respective battery packs 50a to 60d.

The present disclosure is not limited to the descriptions of each of the first and second embodiments, and the descriptions of each of the first and second embodiments can be widely modified within the scope of the present disclosure.

Each of the battery monitoring systems 1 and 1A uses photocouplers for all the serial communications between the control circuit 11 and the respective monitoring ICs and/or between the monitoring ICs, but the present disclosure is not limited thereto. Specifically, in a modified battery monitoring system, a photocoupler can be used for at least one of the serial communications interfaces between the control circuit 11 and the respective monitoring ICs and/or between the monitoring ICs. In the modified battery monitoring system, other serial-communication devices can be used for the remaining serial communications between the control circuit 11 and the respective monitoring ICs and/or between the monitoring ICs. For example, RS-232C transceivers can be used as the serial-communication devices.

Like the battery monitoring systems 1 and 1A, the modified battery monitoring system can result in reduction of:

the number of electrical components of the modified battery monitoring system;

the manufacturing cost of the modified battery monitoring system;

improvement of resistance thereof against noise.

In the battery monitoring system 1 according to the first embodiment, photocouplers can be used for only the serial communications between the control circuit 11 and the respective monitoring ICs 21a and 21d, and other serial-communication devices can be used for the remaining serial communications between the respective monitoring ICs. This modified battery monitoring system results in improvement of:

resistance thereof against noise; and

serial communications between the low-voltage portion and the high-voltage portion that are electrically isolated from each other while maintaining, at a lower level, each of: the number of electrical components of the modified battery monitoring system; and the manufacturing cost of the modified battery monitoring system.

For example, coupling capacitors can be used for the serial communications between the respective monitoring ICs.

The photocouplers are used as isolators between the low-voltage portion and the high-voltage portion in each of the battery monitoring systems 1 and 1A, but the present disclosure is not limited thereto. Specifically, other isolators can be used for communicably connecting between the Low-voltage portion and the high-voltage portion while electrically isolating them from each other in each of the battery monitoring systems 1 and 1A. Specifically, each of the other isolators is comprised of an input portion with a first resistance, and an output portion with, a second resistance lower than the first resistance; the second portion is electrically isolated from the input portion. Thus, a large amount of current is required to flow through the first portion, and a small amount of current is required to flow through the second portion during serial communications. For example, digital isolators, each of which transfers signals using a pair of magnetic coils magnetically coupled to each other, can be used as the other isolators.

Each of the monitoring ICs 21a to 21d is configured to monitor the respective voltages across all the cells included in a corresponding one of the battery packs 50a to 50d, but the present disclosure is not limited thereto. Specifically, each of the monitoring ICs 21a to 21d can be configured to:

monitor currents flowing through the respective cells included in a corresponding one of the battery packs 50a to 50d; or

monitor temperatures of or around the respective cells included in a corresponding one of the battery packs 50a to 50d.

Specifically, each of the monitoring ICs 21a to 21d can be configured to monitor physical parameters indicative of the states of all the cells included in a corresponding one of the battery packs 50a to 50d. Because the physical parameters monitored by each of the monitoring les 21a to 21d represent the state of a corresponding one of the battery packs 50a to 50d, each of the monitoring ICs 21a to 21d can also be configured to monitor the state of a corresponding one of the battery packs 50a to 50d.

In each of the first and second embodiment, a plurality of battery packs can be provided, and each of the monitoring ICs 21a to 21d can be configured to monitor the state of two or more battery packs in the plurality of battery packs.

While illustrative embodiments of the present disclosure have been described herein, the present disclosure is not limited to the embodiments described herein, but includes any and all embodiments having modifications, omissions, combinations (e.g., of aspects across various embodiments), adaptations and/or alternations as would be appreciated by those in the art based on the present disclosure. The limitations in the claims are to be interpreted broadly based on the language employed in the claims and not limited to examples described in the present specification or during the prosecution of the application, which examples are to be construed as non-exclusive.

What is claimed is:

1. A system for monitoring at least one of: a state of a battery pack comprising a plurality of cells; and a state of the plurality of cells, the system comprising:
a control circuit that controls the battery pack;
a control substrate on which the control circuit is mounted;
a plurality of monitoring circuits, each of the plurality of monitoring circuits monitoring a physical parameter indicative of the at least one of the state of the battery pack and the state of the plurality of cells, and sending the physical parameter to the control circuit,
the control circuit receiving the physical parameter sent from each of the plurality of monitoring circuits, and sending a control instruction based on the physical parameter to at least one of the plurality of monitoring circuits; and
a plurality of monitoring substrates on which the respective monitoring circuits are mounted; and
an isolator member having an input portion and an output portion, the input portion and output portion being configured such that an input current flowing through the input portion is larger than an output current flowing through the output portion, the output portion being electrically isolated from the input portion,
the input portion and the output portion of the isolator member being connected respectively to a first circuit and a second circuit included in a group of the control circuit and the plurality of monitoring circuits, the first circuit and the second circuit being selected for the isolator member,
the first circuit serving as a sender, the second circuit serving as a receiver, the isolator member transferring serial data sent from the sender to the receiver while the sender is electrically isolated from the receiver,
the isolator being mounted on a substrate included in the control and monitoring substrates, the receiver being mounted on the substrate included in the control and monitoring substrates.

2. The system according to claim 1, wherein:
the plurality of monitoring substrates include a first monitoring substrate on which one of the plurality of monitoring circuits is mounted as a first monitoring circuit, and a second monitoring substrate on which another one of the plurality of monitoring circuits is mounted as a second monitoring circuit, the first monitoring circuit, at least one other monitoring circuit, and the second monitoring circuit included in the plurality of monitoring circuits being sequentially communicable in this order;
the isolator member includes:
a first isolator having a first input portion defined as the input portion and a first output portion defined as the output portion, the first input portion and the first output portion being connected respectively to the control circuit and the first monitoring circuit 21a, the control circuit and the first monitoring circuit corresponding to the first circuit and the second circuit selected for the first isolator; and
a second isolator having a second input portion defined as the input portion and a second output portion defined as the output portion, the second input portion and the second output portion being connected respectively to the second monitoring circuit and the control circuit, the second monitoring circuit and the control circuit corresponding to the first circuit and the second circuit selected for the second isolator; and
the control circuit serves as the sender to send, via the first isolator, the control instruction to the first monitoring circuit as the serial data while the control circuit is electrically isolated from the first monitoring circuit, the first monitoring circuit serving as the receiver, the first isolator being mounted on the first monitoring substrate;
the first monitoring circuit sends the control instruction to the second monitoring circuit via the at least one other monitoring circuit; and
the second monitoring circuit serves as the sender to send, via the second isolator, a response to the control instruction to the control circuit as the serial data while the second monitoring circuit is electrically isolated from the control circuit, the control circuit serving as the receiver, the second isolator being mounted on the control substrate.

3. The system according to claim 2, wherein:
the at least one other monitoring circuit includes at least one third monitoring circuit;
the plurality of monitoring substrates include at least one third monitoring substrate on which the at least one third monitoring circuit is mounted; and
the isolator member includes:
a plurality of third isolators mounted respectively on the second monitoring substrate and the at least one third monitoring substrate,
the control instruction sent from the first monitoring circuit being configured to be transferred in a sequential order of the first monitoring circuit, the at least one third monitoring circuit, and the second monitoring circuit through the third isolators while the first monitoring circuit, the at least one third monitoring circuit, and the second monitoring circuit are electrically isolated from each other.

4. The system according to claim 1, wherein:
the isolator member includes:
first isolators each having a first input portion defined as the input portion and a first output portion defined as the output portion,
the first input portion and the first output portion of each of the first isolators being connected respectively to the control circuit and a corresponding one of the plurality of monitoring circuits, the control circuit and the corresponding one of the plurality of monitoring circuits being selected as the first circuit and the second circuit for each of the first isolators; and
second isolators each having a second input portion defined as the input portion and a second output portion defined as the output portion, the second input portion and the second output portion of each of the second isolators being connected respectively to a corresponding one of the plurality of monitoring circuits and the control circuit, the corresponding one of the plurality of monitoring circuits and the control circuit being selected as the first circuit and the second circuit for each of the second isolators;
the control circuit serves as the sender to send the control instruction to each of the plurality of monitoring circuits via a corresponding one of the first isolators as the serial data while electrically isolating the control circuit and each of the first isolators, each of the plurality of monitoring circuits serving as the receiver, each of the first isolators being mounted on a corresponding one of the plurality of monitoring substrates; and
each of the plurality of monitoring circuits serves as the sender to send a response to the control instruction to the control circuit via a corresponding one of the second isolators as the serial data while electrically isolating each of the plurality of monitoring circuits and the control circuit, the control circuit serving as the receiver, each of the second isolators being mounted on the control substrate.

5. The system according to claim 1, wherein the isolator member comprises a photocoupler.

6. The system according to claim 2, wherein each of the first isolator and the second isolator comprises a photocoupler.

7. The system according to claim 4, wherein each of the first isolators and the second isolators comprises a photocoupler.

8. The system according to claim 1, wherein the plurality of monitoring substrates have ground portions separated from each other.

9. The system according to claim 8, wherein the ground portions of the plurality of monitoring substrates have reference potentials that are different from each other.
